(19) United States
(12) Patent Application Publication
(10) Pub. No.: US 2008/0315171 A1
(43) Pub. Date: Dec. 25, 2008

(54) INTEGRATED CIRCUIT INCLUDING VERTICAL DIODE

(76) Inventors: Thomas Happ, Tarrytown, NY (US); Thomas Nirschl, Essex Junction, VT (US); Jan Boris Philipp, Peekskill, NY (US)

Correspondence Address: DICKE, BILLIG & CZAJA, FIFTH STREET TOWERS, 100 SOUTH FIFTH STREET, SUITE 2250, MINNEAPOLIS, MN, 55402, US

(21) Appl. No.: 11/766,217

(22) Filed: Jun. 21, 2007

(51) Int. Cl. H01L 47/00; H01L 21/44

(52) U.S. Cl. 257/4; 438/655; 257/E47.001; 257/E21.476

(57) ABSTRACT

An integrated circuit includes a diode including a first polarity region and a second polarity region. The second polarity region contacts a bottom and sidewalls of the first polarity region. The integrated circuit includes a first electrode coupled to the diode, a second electrode, and resistivity changing material between the first electrode and the second electrode.

### BACKGROUND

One type of memory is resistive memory. Resistive memory utilizes the resistance value of a memory element to store one or more bits of data. For example, a memory element programmed to have a high resistance value may represent a logic “1” data bit value and a memory element programmed to have a low resistance value may represent a logic “0” data bit value. Typically, the resistance value of the memory element is switched electrically by applying a voltage pulse or a current pulse to the memory element.

One type of resistive memory is phase change memory. Phase change memory uses a phase change material in the resistive memory element. The phase change material exhibits at least two different states. The states of the phase change material may be referred to as the amorphous state and the crystalline state, where the amorphous state involves a more disordered atomic structure and the crystalline state involves a more ordered lattice. The amorphous state usually exhibits higher resistivity than the crystalline state. Also, some phase change materials exhibit multiple crystalline states, e.g. a face-centered cubic (FCC) state and a hexagonal closest packing (HCP) state, which have different resistivities and may be used to store bits of data. In the following description, the amorphous state generally refers to the state having the higher resistivity and the crystalline state generally refers to the state having the lower resistivity.

Phase changes in the phase change materials may be induced reversibly. In this way, the memory may change from the amorphous state to the crystalline state and from the crystalline state to the amorphous state in response to temperature changes. The temperature changes of the phase change material may be achieved by driving current through the phase change material itself or by driving current through a resistive heater adjacent the phase change material. With both of these methods, controllable heating of the phase change material causes controllable phase change within the phase change material.

A phase change memory including a memory array having a plurality of memory cells that are made of phase change material may be programmed to store data utilizing the memory states of the phase change material. One way to read and write data in such a phase change memory device is to control a current and/or a voltage pulse that is applied to the phase change material. The level of current and/or voltage generally corresponds to the temperature induced within the phase change material in each memory cell.

To achieve higher density phase change memories, a phase change memory cell can store multiple bits of data. Multi-bit storage in a phase change memory cell can be achieved by programming the phase change material to have intermediate resistance values or states, where the multi-bit or multilevel phase change memory cell can be written to more than two states. If the phase change memory cell is programmed to one of three different resistance levels, 1.5 bits of data per cell can be stored. If the phase change memory cell is programmed to one of four different resistance levels, two bits of data per cell can be stored, and so on. To program a phase change memory cell to an intermediate resistance value, the amount of crystalline material coexisting with amorphous material and hence the cell resistance is controlled via a suitable write strategy.

Higher density phase change memories can also be achieved by reducing the physical size of the memory cells. Increasing the density of a phase change memory increases the amount of data that can be stored within the memory while at the same time typically reducing the cost of the memory.

For these and other reasons, there is a need for the present invention.

### SUMMARY

One embodiment provides an integrated circuit. The integrated circuit includes a diode including a first polarity region and a second polarity region. The second polarity region contacts a bottom and sidewalls of the first polarity region. The integrated circuit includes a first electrode coupled to the diode, a second electrode, and resistivity changing material between the first electrode and the second electrode.

### BRIEF DESCRIPTION OF THE DRAWINGS

The accompanying drawings are included to provide a further understanding of the present invention and are incorporated in and constitute a part of this specification. The drawings illustrate the embodiments of the present invention and together with the description serve to explain the principles of the invention. Other embodiments of the present invention and many of the intended advantages of the present invention will be readily appreciated as they become better understood by reference to the following detailed description. The elements of the drawings are not necessarily to scale relative to each other. Like reference numerals designate corresponding similar parts.

FIG. 1 is a block diagram illustrating one embodiment of a system.

FIG. 2 is a diagram illustrating one embodiment of a memory device.

FIG. 3 illustrates a cross-sectional view of one embodiment of a memory cell.

FIG. 4 illustrates a cross-sectional view of another embodiment of a memory cell.

FIG. 5 illustrates a cross-sectional view of another embodiment of a memory cell.

FIG. 6 illustrates a cross-sectional view of another embodiment of a memory cell.

FIG. 7 illustrates a cross-sectional view of one embodiment of a wafer after depositing a protection material layer and performing ion implantation.

FIG. 8 illustrates a cross-sectional view of one embodiment of the wafer after depositing a first dielectric material layer and a second optional dielectric material layer.

FIG. 9 illustrates a cross-sectional view of one embodiment of the wafer after etching the first dielectric material layer and the optional second dielectric material layer.

FIG. 10 illustrates a cross-sectional view of one embodiment of the wafer after implanting a P+ implant.

FIG. 11 illustrates a cross-sectional view of one embodiment of the wafer after etching the protection material layer.

FIG. 12 illustrates a cross-sectional view of one embodiment of the wafer after forming silicide.

FIG. 13 illustrates a cross-sectional view of one embodiment of the wafer after depositing a spacer material layer.

FIG. 14 illustrates a cross-sectional view of one embodiment of the wafer after etching the spacer material layer.

FIG. 15A illustrates a cross-sectional view of one embodiment of the wafer after depositing an electrode material.

FIG. 15B illustrates a top view of one embodiment of the wafer after depositing the electrode material.

FIG. 16 illustrates a cross-sectional view of one embodiment of the wafer after depositing an optional hard mask material layer.

FIG. 17 illustrates a top view of one embodiment of the wafer after forming shallow trench isolation and removing the hard mask material layer.

FIG. 18 illustrates a cross-sectional view of one embodiment of the wafer after depositing a phase change material layer and an electrode material layer.

FIG. 19 illustrates a top view of one embodiment of the wafer after etching the phase change material layer and the electrode material layer.

FIG. 20 illustrates a cross-sectional view of one embodiment of the wafer after depositing an electrode material and a dielectric material.

FIG. 21 illustrates a cross-sectional view of one embodiment of the wafer after depositing an electrode material and a phase change material.

FIG. 22 illustrates a cross-sectional view of one embodiment of the wafer after depositing an electrode material and a phase change material.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments of the present invention can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

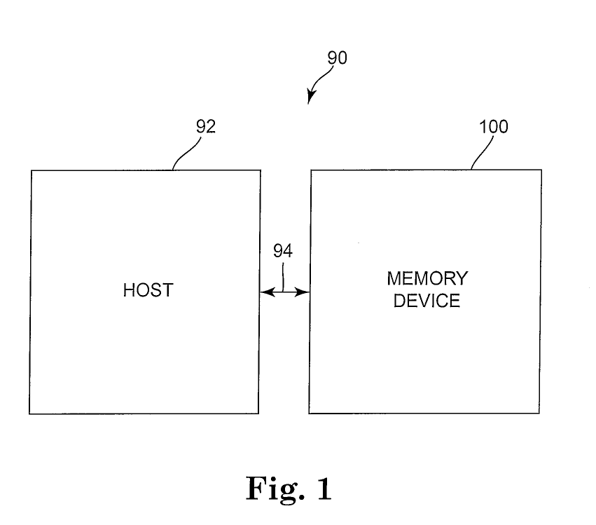

FIG. 1 is block diagram illustrating one embodiment of a system 90. System 90 includes a host 92 and a memory device 100. Host 92 is communicatively coupled to memory device 100 through communication link 94. Host 92 includes a computer (e.g., desktop, laptop, handheld), portable electronic device (e.g., cellular phone, personal digital assistant (PDA), MP3 player, video player), or any other suitable device that uses memory. Memory device 100 provides memory for host 92. In one embodiment, memory device 100 includes a phase change memory device or other suitable resistive or resistivity changing memory device.

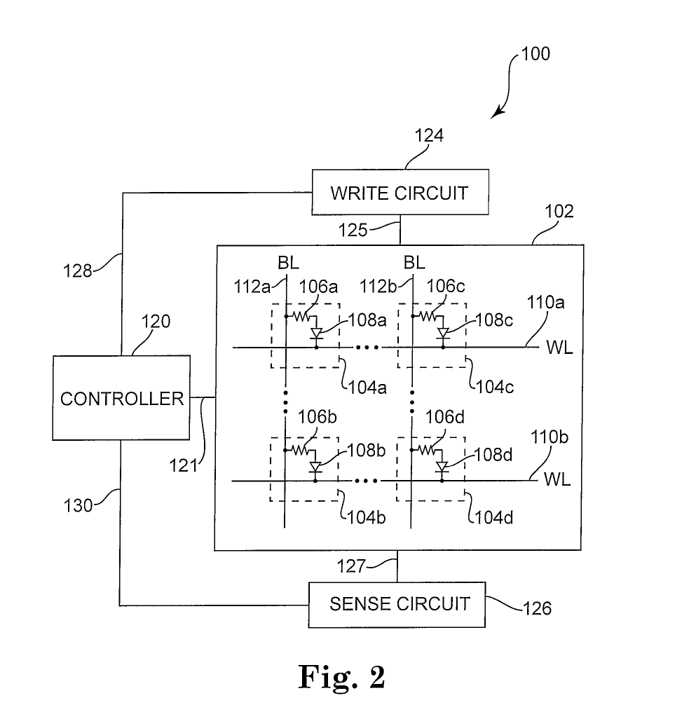

FIG. 2 is a diagram illustrating one embodiment of memory device 100. Memory device 100 includes a write circuit 124, a controller 120, a memory array 102, and a sense circuit 126. Memory array 102 includes a plurality of resistive memory cells 104a-104d (collectively referred to as resistive memory cells 104), a plurality of bit lines (BLs) 112a-112b (collectively referred to as bit lines 112), and a plurality of word lines (WLs) 110a-110b (collectively referred to as word lines 110). In one embodiment, resistive memory cells 104 are phase change memory cells. In other embodiments, resistive memory cells 104 are another suitable type of resistive memory cells or resistivity changing memory cells.

Each memory cell 104 includes a phase change element 106 and a diode 108. By using diodes 108 to access bits within memory array 102, a 4F² memory cell size is achieved, where “F” is the minimum lithographic feature size. Diodes 108 are fabricated using an epitaxy-free process.

As used herein, the term “electrically coupled” is not meant to mean that the elements must be directly coupled together and intervening elements may be provided between the “electrically coupled” elements.

Memory array 102 is electrically coupled to write circuit 124 through signal path 125, to controller 120 through signal path 121, and to sense circuit 126 through signal path 127. Controller 120 is electrically coupled to write circuit 124 through signal path 128 and to sense circuit 126 through signal path 130. Each phase change memory cell 104 is electrically coupled to a word line 110 and a bit line 112. Phase change memory cell 104a is electrically coupled to bit line 112a and word line 110a, and phase change memory cell 104b is electrically coupled to bit line 112a and word line 110b. Phase change memory cell 104c is electrically coupled to bit line 112b and word line 110a, and phase change memory cell 104d is electrically coupled to bit line 112b and word line 110b.

Each phase change memory cell 104 includes a phase change element 106 and a diode 108. Phase change memory cell 104a includes phase change element 106a and diode 108a. One side of phase change element 106a is electrically coupled to bit line 112a, and the other side of phase change element 106a is electrically coupled to one side of diode 108a. The other side of diode 108a is electrically coupled to word line 110a.

Phase change memory cell 104b includes phase change element 106b and diode 108b. One side of phase change element 106b is electrically coupled to bit line 112a, and the other side of phase change element 106b is electrically coupled to one side of diode 108b. The other side of diode 108b is electrically coupled to word line 110b.

Phase change memory cell 104c includes phase change element 106c and diode 108c. One side of phase change element 106c is electrically coupled to bit line 112b and the other side of phase change element 106c is electrically coupled to one side of diode 108c. The other side of diode 108c is electrically coupled to word line 110a.

Phase change memory cell 104d includes phase change element 106d and diode 108d. One side of phase change element 106d is electrically coupled to bit line 112b and the other side of phase change element 106d is electrically coupled to one side of diode 108d. The other side of diode 108d is electrically coupled to word line 110b.

In another embodiment, each phase change element 106 is electrically coupled to a word line 110 and each diode 108 is electrically coupled to a bit line 112. For example, for phase change memory cell 104a, one side of phase change element 106a is electrically coupled word line 110a. The other side of phase change element 106a is electrically coupled to one side of diode 108a. The other side of diode 108a is electrically coupled to bit line 112a.

In one embodiment, each resistive memory element 106 is a phase change element that comprises a phase change material that may be made up of a variety of materials in accordance with the present invention. Generally, chalcogenide alloys that contain one or more elements from Group VI of the periodic table are useful as such materials. In one embodiment, the phase change material is made up of a chalcogenide compound material, such as GeSbTe, SbTe, GeTe, or AgInSbTe. In another embodiment, the phase change material is chalcogen free, such as GeSb, GaSb, InSb, or GeGaInSb. In other embodiments, the phase change material is made up of any suitable material including one or more of the elements Ge, Sb, Te, Ga, As, In, Se, and S.

Each phase change element may be changed from an amorphous state to a crystalline state or from a crystalline state to an amorphous state under the influence of temperature change. The amount of crystalline material coexisting with amorphous material in the phase change material of one of the phase change elements thereby defines two or more states for storing data within memory device 100. In the amorphous state, a phase change material exhibits significantly higher resistivity than in the crystalline state. Therefore, the two or more states of the phase change elements differ in their electrical resistivity. In one embodiment, the two or more states are two states and a binary system is used, wherein the two states are assigned bit values of “0” and “1”. In another embodiment, the two or more states are three states and a ternary system is used, wherein the three states are assigned bit values of “0”, “1”, and “2”. In another embodiment, the two or more states are four states that are assigned multi-bit values, such as “00”, “01”, “10”, and “11”. In other embodiments, the two or more states can be any suitable number of states in the phase change material of a phase change element.

Controller 120 includes a microprocessor, microcontroller, or other suitable logic circuitry for controlling the operation of memory device 100. Controller 120 controls read and write operations of memory device 100 including the application of control and data signals to memory array 102 through write circuit 124 and sense circuit 126. In one embodiment, write circuit 124 provides voltage pulses through signal path 125 and bit lines 112 to memory cells 104 to program the memory cells. In other embodiments, write circuit 124 provides current pulses through signal path 125 and bit lines 112 to memory cells 104 to program the memory cells.

Sense circuit 126 reads each of the two or more states of memory cells 104 through bit lines 112 and signal path 127. In one embodiment, to read the resistance of one of the memory cells 104, sense circuit 126 provides current that flows through one of the memory cells 104. Sense circuit 126 then reads the voltage across that one of the memory cells 104. In another embodiment, sense circuit 126 provides voltage across one of the memory cells 104 and reads the current that flows through that one of the memory cells 104. In another embodiment, write circuit 124 provides voltage across one of the memory cells 104 and sense circuit 126 reads the current that flows through that one of the memory cells 104. In another embodiment, write circuit 124 provides current that flows through one of the memory cells 104 and sense circuit 126 reads the voltage across that one of the memory cells 104.

In one embodiment, during a “set” operation of phase change memory cell 104a, a set current or voltage pulse is selectively enabled by write circuit 124 and sent through bit line 112a to phase change element 106a thereby heating phase change element 106a above its crystallization temperature (but usually below its melting temperature). In this way, phase change element 106a reaches its crystalline state or a partially crystalline and partially amorphous state during this set operation. During a “reset” operation of phase change memory cell 104a, a reset current or voltage pulse is selectively enabled by write circuit 124 and sent through bit line 112a to phase change element 106a. The reset current or voltage quickly heats phase change element 106a above its melting temperature. After the current or voltage pulse is turned off, phase change element 106a quickly quench cools into the amorphous state or a partially amorphous and partially crystalline state.

Phase change memory cells 104b-104d and other phase change memory cells 104 in memory array 102 are set and reset similarly to phase change memory cell 104a using a similar current or voltage pulse. In other embodiments, for other types of resistive memory cells, write circuit 124 provides suitable programming pulses to program the resistive memory cells 104 to the desired state.

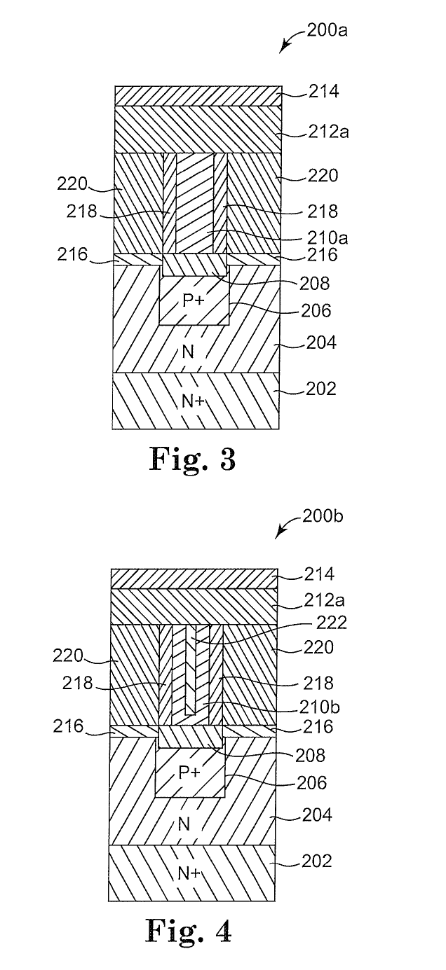

FIG. 3 illustrates a cross-sectional view of one embodiment of a memory cell 200a. In one embodiment, each memory cell 104 is similar to memory cell 200a. In one embodiment, memory cell 200a is a mushroom memory cell including a sublithographic strip heater. Memory cell 200a includes N+ word line 202, N region 204, P+ region 206, silicide contact 208, protection material 216, bottom electrode 210a, phase change element 212a, top electrode 214, spacers 218, and dielectric material 220. P+ region 206 and N region 204 form a diode 108. In another embodiment, the polarity of the diode is reversed, such that the diode is formed by an N+ region and a P region, which is coupled to a P+ word line.

Word line 202 includes an N+ region formed by ion implantation into a P type substrate and separated by shallow trench isolation (STI). The top of word line 202 contacts the bottom of N region 204. N region 204 is formed by ion implantation into the P type substrate. N region 204 contacts the bottom and sidewalls of P+ region 206. P+ region 206 is formed by ion implantation into N region 204. The top of N region 204 contacts the bottom of protection material 216. Protection material 216 includes an oxide or other suitable material. The top of P+ region 206 contacts the bottom of silicide contact 208. Silicide contact 208 includes CoSi, TiSi, NiSi, NiPtSi, WSi, TaSi, or other suitable silicide. Sidewalls of silicide contact 208 contact sidewalls of protection material 216. The top of silicide contact 208 contacts the bottom of bottom electrode 210a and the bottom of spacers 218.

Bottom electrode 210a includes TiN, TaN, C, W, Al, Ti, Ta, TiSiN, TaSiN, TiAlN, TaAlN, Cu, or other suitable electrode material. Bottom electrode 210a has a sublithographic cross-sectional width defined by spacers 218. The top of bottom electrode 210a contacts the bottom of phase change element 212a. Phase change element 212a provides a storage location for storing one or more bits of data. The active or phase change region of phase change element 212a is at the interface between phase change element 212a and bottom electrode 210a. Sidewalls of bottom electrode 210a contact sidewalls of spacers 218. Spacers 218 include SiN or other suitable spacer material. The top of phase change element 212a contacts the bottom of top electrode 214. Top electrode 214 includes TiN, TaN, C, W, Al, Ti, Ta, TiSiN, TaSiN, TiAlN, Cu, or other suitable electrode material. Sidewalls of spacers 218 contact sidewalls of dielectric material 220. Dielectric material 220 includes SiO₂, SiOₓ, SiN, fluorinated silica glass (FSG), boro-phosphorous silicate glass (BPSG), boro-silicate glass (BSG), or other suitable dielectric material.

The current path through memory cell 200a is from top electrode 214 through phase change element 212a to bottom electrode 210a. From bottom electrode 210a, the current flows through silicide contact 208a and the diode formed by P+ region 206 and N region 204. From N region 204 the current flows through N+ word line 202. The cross-sectional width of the interface area between phase change element 212a and bottom electrode 210a defines the current density through the interface and thus the power used to program memory cell 200a. By reducing the cross-sectional width of the interface area, the current density is increased, thus reducing the power used to program memory cell 200a.

During operation of memory cell 200a, current or voltage pulses are applied between top electrode 214 and word line 202 to program memory cell 200a. During a set operation of memory cell 200a, a set current or voltage pulse is selectively enabled by write circuit 124 and sent through a bit line to top electrode 214. From top electrode 214, the set current or voltage pulse is sent through phase change element 212a thereby heating the phase change material above its crystallization temperature (but usually below its melting temperature). In this way, the phase change material reaches a crystalline state or a partially crystalline and partially amorphous state during the set operation.

During a reset operation of memory cell 200a, a reset current or voltage pulse is selectively enabled by write circuit 124 and sent through a bit line to top electrode 214. From top electrode 214, the reset current or voltage pulse is sent through phase change element 212a. The reset current or voltage quickly heats the phase change material above its melting temperature. After the current or voltage pulse is turned off, the phase change material quickly quench cools into an amorphous state or a partially amorphous and partially crystalline state.

FIG. 4 illustrates a cross-sectional view of another embodiment of a memory cell 200b. In one embodiment, each memory cell 104 is similar to memory cell 200b. In one embodiment, memory cell 200b is a mushroom memory cell. Memory cell 200b is similar to memory cell 200a previously described and illustrated with reference to FIG. 3, except that in memory cell 200b bottom electrode 210a is replaced with bottom electrode 210b and dielectric material 222.

In this embodiment, bottom electrode 210b is a U-shaped electrode. The inner surface of electrode 210b contacts dielectric material 222. Dielectric material 222 includes SiO₂, SiOₓ, SiN, FSG, BPSG, BSG, or other suitable dielectric material. In this embodiment, the interface area between bottom electrode 210b and phase change element 212a is further reduced. The reduced interface area provides a higher current density and thus reduces the current used to program memory cell 200b. Memory cell 200b is programmed similarly to memory cell 200a previously described and illustrated with reference to FIG. 3.

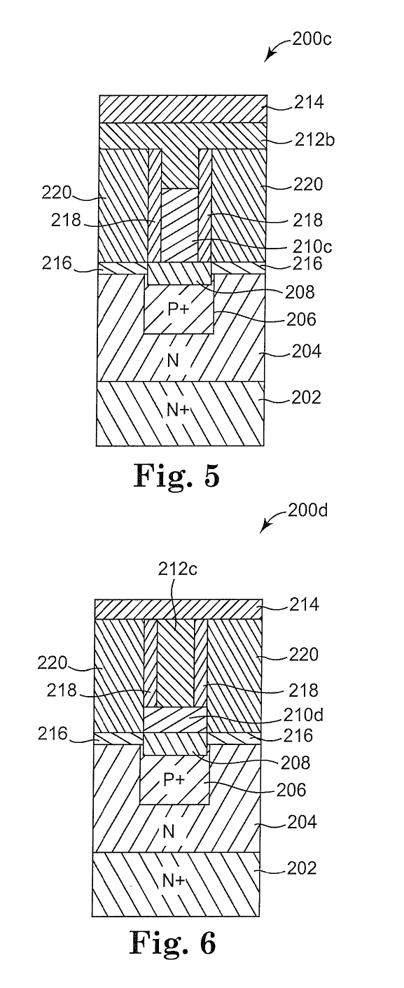

FIG. 5 illustrates a cross-sectional view of another embodiment of a memory cell 200c. In one embodiment, each memory cell 104 is similar to memory cell 200c. In one embodiment, memory cell 200c is a recessed mushroom memory cell. Memory cell 200c is similar to memory cell 200a previously described and illustrated with reference to FIG. 3, except that in memory cell 200c phase change element 212a is replace with phase change element 212b and bottom electrode 210a is replaced with bottom electrode 210c.

In this embodiment, bottom electrode 210c is recessed within the area defined by spacers 218. The top of bottom electrode 210c contacts the bottom of phase change element 212b, which includes a first portion that is also within the area defined by spacers 218. Sidewalls of the first portion of phase change element 212b and sidewalls of bottom electrode 210c contact sidewalls of spacers 218. The bottom of top electrode 214 contacts the top of phase change element 212b. Memory cell 200c is programmed similarly to memory cell 200a previously described and illustrated with reference to FIG. 3.

FIG. 6 illustrates a cross-sectional view of another embodiment of a memory cell 200d. In one embodiment, each memory cell 104 is similar to memory cell 200d. In one embodiment, memory cell 200d is a pore memory cell. Memory cell 200d is similar to memory cell 200c previously described and illustrated with reference to FIG. 5, except that in memory cell 200d phase change element 212b is replaced with phase change element 212c and bottom electrode 210c is replaced with bottom electrode 210d.

In this embodiment, bottom electrode 210d is recessed with an area defined by dielectric material 220. Sidewalls of bottom electrode 210d contact sidewalls of dielectric material 220. The top of bottom electrode 210d contacts the bottom of spacers 218 and the bottom of phase change element 212c. Phase change element 212c is within the area defined by spacers 218. Sidewalls of phase change element 212c contact sidewalls of spacers 218. The bottom of top electrode 214 contacts the top of phase change element 212c, the top of spacers 218, and the top of dielectric material 220. Memory cell 200d is programmed similarly to memory cell 200a previously described and illustrated with reference to FIG. 3.

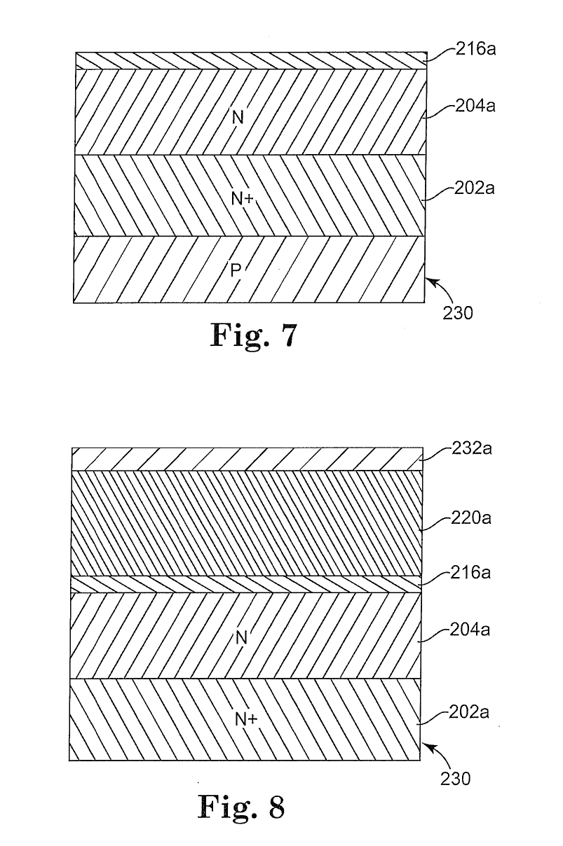

The following FIGS. 7-22 illustrate embodiments for fabricating memory cells 200a-200d previously described and illustrated with reference to FIGS. 3-6. In one embodiment, logic transistors are formed in the periphery of the memory array before the diodes are formed in the memory array. In another embodiment, the diodes are formed in the memory array before the logic transistors are formed in the periphery of the memory array. The following description focuses solely on the memory array portion of the integrated circuit.

FIG. 7 illustrates a cross-sectional view of one embodiment of a wafer 230 after depositing a protection material layer 216a and performing ion implantation. A protection material layer, such as an oxide or other suitable protection material is deposited over a P type substrate. Protection material layer 216a is deposited using chemical vapor deposition (CVD), high density plasma-chemical vapor deposition (HDP-CVD), atomic layer deposition (ALD), metal organic chemical vapor deposition (MOCVD), physical vapor deposition (PVD), jet vapor deposition (JVD), or other suitable deposition technique.

A deep N+ implant is implanted into the P type substrate to form N+ region 202a. A medium deep N implant is implanted into the P type substrate to provide N region 204a. N+ region 202a and N region 204a are formed using ion implantation or other suitable epitaxy-free technique. N+ region 202a is used to form word lines 202 in subsequent processing steps. The PN junctions formed between word lines 202 and the P type substrate provide insulation junctions for word lines 202. For simplicity, in the following FIGS. 8-22, the P type substrate is not illustrated.

FIG. 8 illustrates a cross-sectional view of one embodiment of wafer 230 after depositing a first dielectric material layer 220a and an optional second dielectric material layer 232a. A first dielectric material, such as SiN or other suitable dielectric material is deposited over protection material layer 216a to provide first dielectric material layer 220a. First dielectric material layer 220a is deposited using CVD, HDP-CVD, ALD, MOCVD, PVD, JVD, or other suitable deposition technique. In one embodiment, first dielectric material layer 220a is thicker than protection material layer 216a.

A second dielectric material, such as SiO₂ or other suitable dielectric material is deposited over first dielectric material layer 220a to provide optional second dielectric material layer 232a. Second dielectric material layer 232a is deposited using CVD, HDP-CVD, ALD, MOCVD, PVD, JVD, or other suitable deposition technique. In one embodiment, optional second dielectric material layer 232a is thinner than first dielectric material layer 220a.

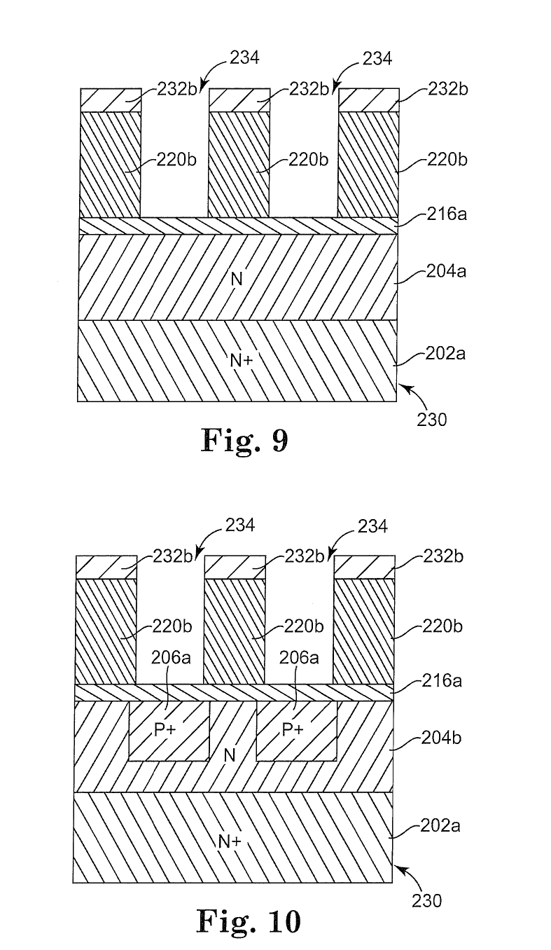

FIG. 9 illustrates a cross-sectional view of one embodiment of wafer 230 after etching first dielectric material layer 220a and optional second dielectric material layer 232a. Second dielectric material layer 232a and first dielectric material layer 220a are etched to form openings 234 exposing portions of protection material layer 216a and to provide first dielectric material layer 220b and second dielectric material layer 232b. In one embodiment, openings 234 are trenches.

FIG. 10 illustrates a cross-sectional view of one embodiment of wafer 230 after implanting a P+ implant. P+ implants are implanted into N region 204b under the exposed portions of protection material layer 216a to form P+ regions 206a and to provide N region 204b. P+ regions 206a are formed using ion implantation or other suitable technique.

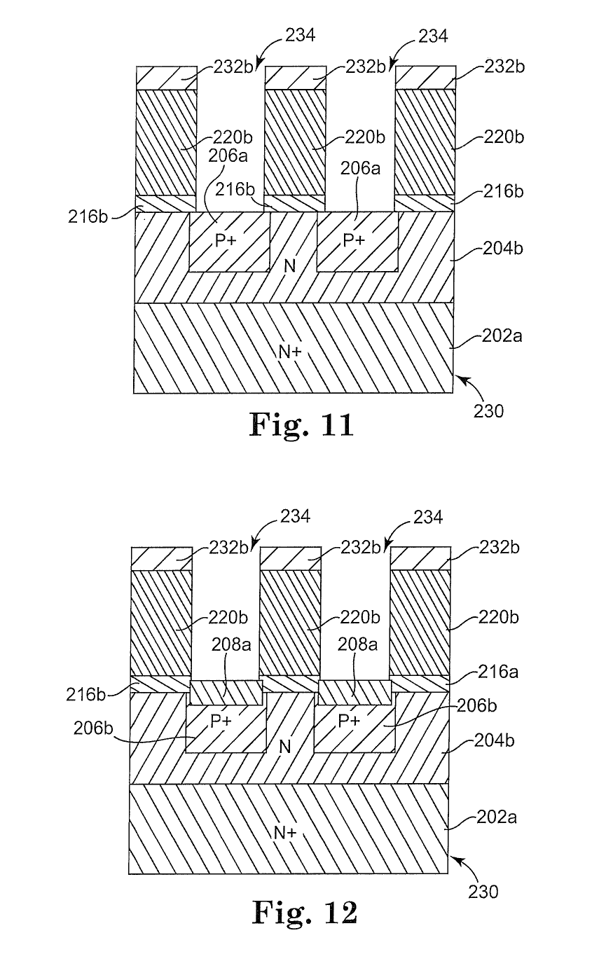

FIG. 11 illustrates a cross-sectional view of one embodiment of wafer 230 after etching protection material layer 216a. The exposed portions of protection material layer 216a are etched to expose P+ regions 206a and to provide protection material layer 216b. Protection material layer 216a is etched using a wet or dry etch.

FIG. 12 illustrates a cross-sectional view of one embodiment of wafer 230 after forming silicide 208a. Silicide 208a, such as CoSi, TiSi, NiSi, TaSi, or other suitable silicide is formed over the exposed portions of P+ regions 206a to provide P+ regions 206b.

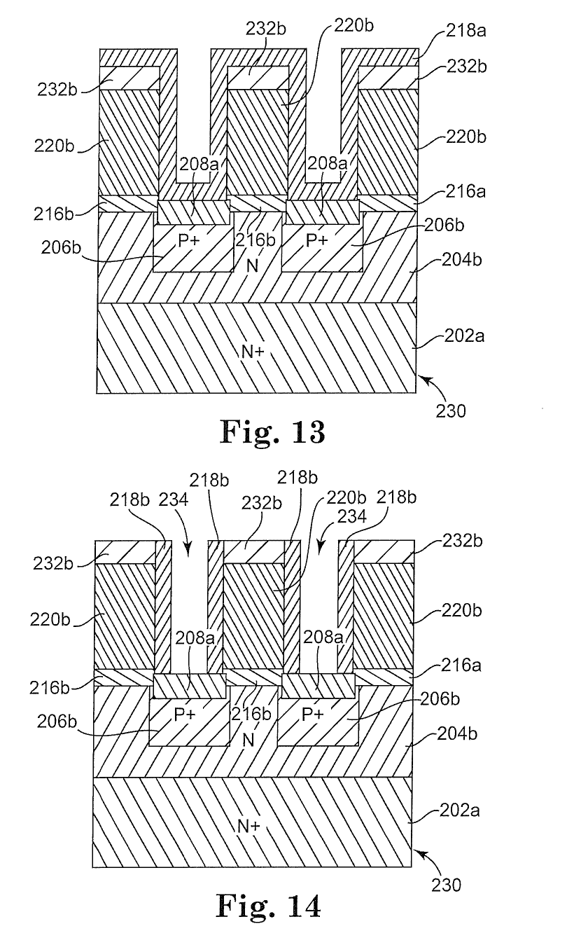

FIG. 13 illustrates a cross-sectional view of one embodiment of wafer 230 after depositing a spacer material layer 218a. A spacer material, such as SiN or other suitable dielectric material is conformally deposited over exposed portions of optional second dielectric material layer 232b, first dielectric material layer 220b, and silicide 208a to provide spacer material layer 218a. Spacer material layer 218a is deposited using CVD, HDP-CVD, ALD, MOCVD, PVD, JVD, or other suitable deposition technique.

FIG. 14 illustrates a cross-sectional view of one embodiment of wafer 230 after etching spacer material layer 218a. Spacer material layer 218a is spacer etched to expose the top of optional second dielectric material layer 232b and a portion of the top of silicide 208a to provide spacers 218b. Spacers 218b reduce the cross-sectional width of openings 234 to a sublithographic value.

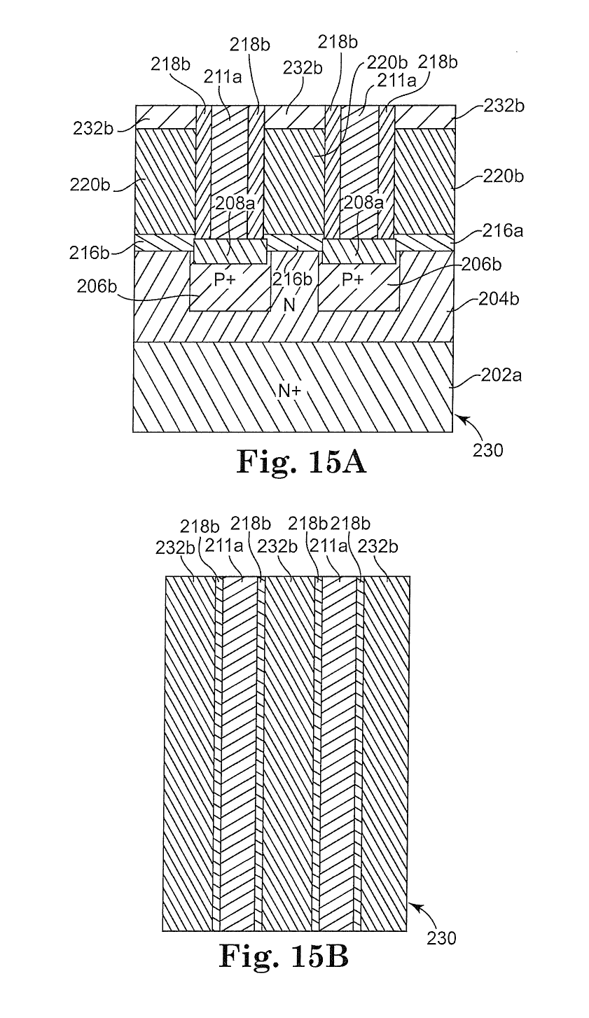

FIG. 15A illustrates a cross-sectional view of one embodiment of wafer 230 after depositing an electrode material 211a. FIG. 15B illustrates a top view of one embodiment of wafer 230 after depositing electrode material 211a. An electrode material, such as TiN, TaN, C, W, Al, Ti, Ta, TiSiN, TaSiN, TiAlN, Cu, or other suitable electrode material is deposited over exposed portions of optional second dielectric material layer 232b, spacers 218b, and silicide 208a to provide an electrode material layer. The electrode material layer is then planarized to expose second dielectric material layer 232b and to provide electrode material 211a. The electrode material layer is planarized using chemical mechanical planarization (CMP) or another suitable planarization technique.

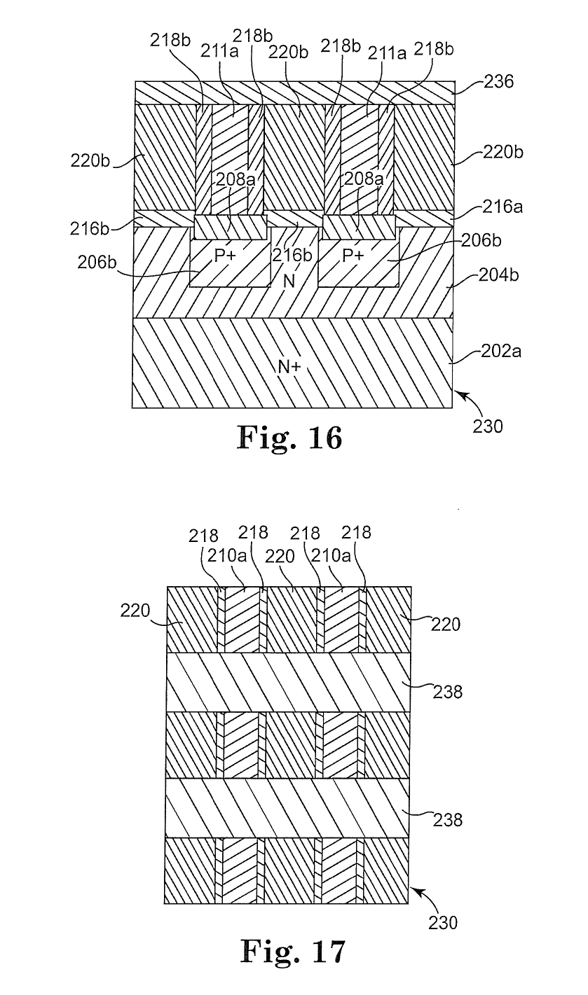

FIG. 16 illustrates a cross-sectional view of one embodiment of wafer 230 after depositing an optional hard mask material layer 236. If optional second dielectric material layer 232b is used, second dielectric material layer 232b, spacers 218b, and electrode material 211a are planarized to remove second dielectric material layer 232b and to expose first dielectric material layer 220b. Second dielectric material layer 232b, spacers 218b, and electrode material 211a are planarized using CMP or another suitable planarization technique.

A hard mask material, such as C or other suitable hard mask material is deposited over exposed portions of first dielectric material layer 220b, spacers 218b, and electrode material 211a to provide optional hard mask material layer 236. Hard mask material layer 236 is deposited using CVD, HDP-CVD, ALD, MOCVD, PVD, JVD, or other suitable deposition technique.

FIG. 17 illustrates a top view of one embodiment of wafer 230 after forming shallow trench isolation and removing hard mask material layer 236. Hard mask material layer 236 is etched to expose portions of first dielectric material layer 220b, spacers 218b, and electrode material 211a. Hard mask material layer 236 is etched in lines perpendicular to the lines of electrode material 211a.

The portions of first dielectric material layer 220b, spacers 218b, electrode material 211a, silicide 208a, P+ regions 206b, N region 204b, and N+ region 202a not protected by the remaining portions of hard mask material layer 236 are then etched to expose the P type substrate and to provide bottom electrodes 210a, spacers 218, dielectric material 220, silicide contacts 208, P+ regions 206, N regions 204, and N+ word lines 202.

A dielectric material, such as SiO₂, SiOₓ, SiN, FSG, BPSG, BSG, or other suitable dielectric material is deposited over exposed portions of the remaining portions of hard mask material layer 236, bottom electrodes 210a, spacers 218, dielectric material 220, silicide contacts 208, P+ regions 206, N regions 204, N+ word lines 202, and the P type substrate to provide a dielectric material layer. The dielectric material layer is then planarized to expose the remaining portions of hard mask material layer 236 and to provide dielectric material 238. The dielectric material layer is planarized using CMP or another suitable planarization technique. Dielectric material 238 provide shallow trench isolation (STI). The remaining portions of hard mask material layer 236 are then removed to expose dielectric material 220, spacers 218, and bottom electrodes 210a.

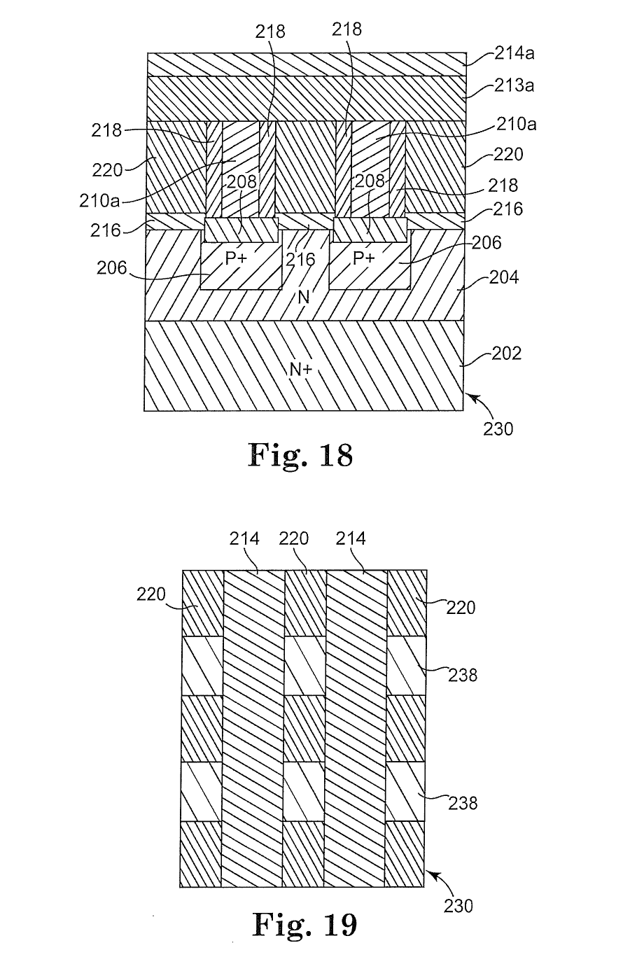

FIG. 18 illustrates a cross-sectional view of one embodiment of wafer 230 after depositing a phase change material layer 213a and an electrode material layer 214a. A phase change material, such as a chalcogenide compound material or other suitable phase change material is deposited over exposed portions of dielectric material 220, spacers 218, bottom electrodes 210a, and dielectric material 238 to provide phase change material layer 213a. Phase change material layer 213a is deposited using CVD, HDP-CVD, ALD, MOCVD, PVD, JVD, or other suitable deposition technique.

An electrode material, such as TiN, TaN, C, W, Al, Ti, Ta, TiSiN, TaSiN, TiAlN, TaAlN, Cu, or other suitable electrode material is deposited over phase change material layer 213a to provide electrode material layer 214a. Electrode material layer 214a is deposited using CVD, HDP-CVD, ALD, MOCVD, PVD, JVD, or other suitable deposition technique.

FIG. 19 illustrates a top view of one embodiment of wafer 230 after etching phase change material layer 213a and electrode material layer 214a. Electrode material layer 214a and phase change material layer 213 a are etched to expose portions of dielectric material 220 and portions of dielectric material 238 to provide phase change elements 212a and top electrodes 214 of memory cells 200a as previously described and illustrated with reference to FIG. 3. Electrode material layer 214a and phase change material layer 213a are etched in lines perpendicular to the lines of dielectric material 238.

A dielectric material, such as SiO₂, SiOₓ, SiN, FSG, BPSG, BSG, or other suitable dielectric material is deposited over exposed portions of top electrodes 214, phase change elements 212a, dielectric material 220, and dielectric material 238 to provide a dielectric material layer. The dielectric material layer is deposited using CVD, HDP-CVD, ALD, MOCVD, PVD, JVD, or other suitable deposition technique. In one embodiment, the dielectric material layer is then planarized to expose top electrodes 214. The dielectric material layer is planarized using CMP or another suitable planarization technique.

In one embodiment, phase change elements 212a and top electrodes 214 are encapsulated with one or more layers of encapsulation material, such as SiN, SiON, or other suitable encapsulation material, before the dielectric material is deposited to fill in around the phase change elements 212a and top electrodes 214. Additional contacts and metallization layers including bit lines 112 may then be formed above and coupled to top electrodes 214.

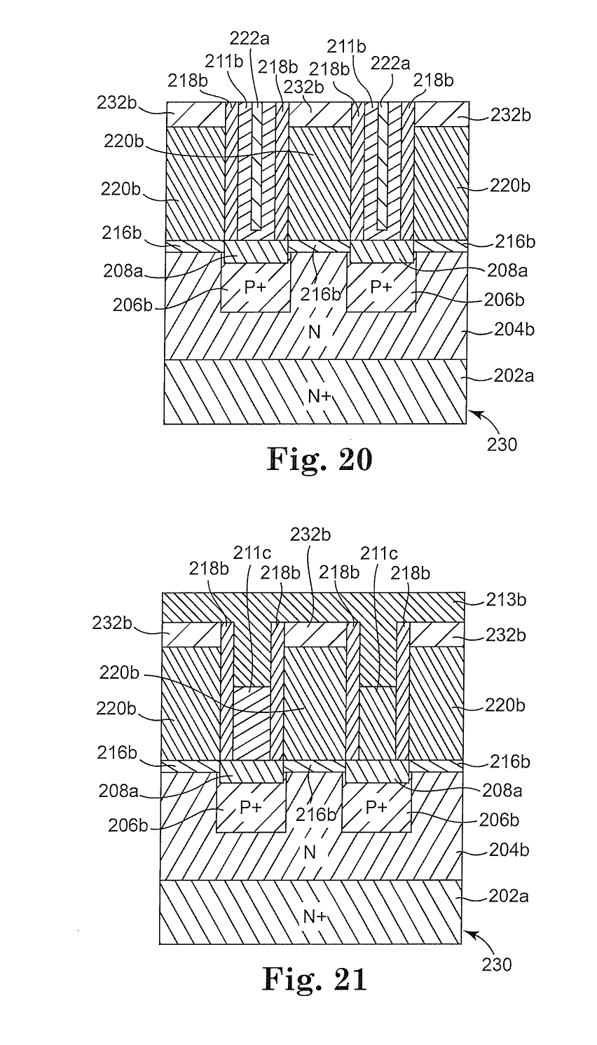

The following FIGS. 20-22 each illustrate embodiments for fabricating memory cells 200b-200d previously described and illustrated with reference to FIG. 4-6.

FIG. 20 illustrates a cross-sectional view of one embodiment of wafer 230 after depositing an electrode material 211b and a dielectric material 222a. Electrode material 211b and dielectric material 222a are deposited after performing the fabrication process previously described and illustrated with reference to FIGS. 7-14. Electrode material, such as TiN, TaN, C, W, Al, Ti, Ta, TiSiN, TaSiN, TiAlN, TaAlN, Cu, or other suitable electrode material is conformally deposited over exposed portions of second dielectric material layer 232b, spacers 218b, and silicide 208a to provide an electrode material layer. The electrode material layer is deposited using CVD, HDP-CVD, ALD, MOCVD, PVD, JVD, or other suitable deposition technique.

A dielectric material, such as SiO₂, SiOₓ, SiN, FSG, BPSG, BSG, or other suitable dielectric material is deposited over the electrode material layer to provide a dielectric material layer. The dielectric material layer is deposited using CVD, HDP-CVD, ALD, MOCVD, PVD, JVD, or other suitable deposition technique. The dielectric material layer and the electrode material layer are then planarized to expose second dielectric material layer 232b and to provide electrode material 211b and dielectric material 222a. The dielectric material layer and the electrode material layer are planarized using CMP or another suitable planarization technique. The fabrication process previously described and illustrated with reference to FIGS. 16-19 is then performed to fabricate memory cells 200b previously described and illustrated with reference to FIG. 4.

FIG. 21 illustrates a cross-sectional view of one embodiment of wafer 230 after depositing electrode material 211c and phase change material 213b. Electrode material 211c and phase change material 213b are deposited after performing the fabrication process previously described and illustrated with reference to FIGS. 7-14. Electrode material, such as TiN, TaN, C, W, Al, Ti, Ta, TiSiN, TaSiN, TiAlN, TaAlN, Cu, or other suitable electrode material is deposited over exposed portions of second dielectric material layer 232b, spacers 218b, and silicide 208a to provide an electrode material layer. The electrode material layer is deposited using CVD, HDP-CVD, ALD, MOCVD, PVD, JVD, or other suitable deposition technique. The electrode material layer is then recess etched to expose second dielectric material layer 232b and a portion of the sidewalls of spacers 218b and to provide electrode material 211c.

A phase change material, such as a chalcogenide compound material or other suitable phase change material is deposited over exposed portions of second dielectric material layer 232b, spacers 218b, and electrode material 211c to provide phase change material layer 213b. Phase change material layer 213b is deposited using CVD, HDP-CVD, ALD, MOCVD, PVD, JVD, or other suitable deposition technique.

The fabrication process previously described and illustrated with reference to FIGS. 16-19 (absent the phase change material deposition illustrated with reference to FIG. 18) is then performed to fabricate memory cells 200c previously described and illustrated with reference to FIG. 5.

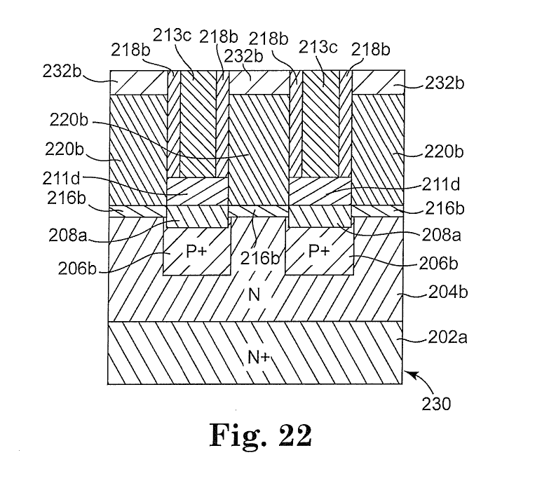

FIG. 22 illustrates a cross-sectional view of one embodiment of wafer 230 after depositing an electrode material 211d and a phase change material 213c. Electrode material 211d is deposited after performing the fabrication process previously described and illustrated with reference to FIGS. 7-12. Electrode material, such as TiN, TaN, C, W, Al, Ti, Ta, TiSiN, TaSiN, TiAlN, TaAlN, Cu, or other suitable electrode material is deposited over exposed portions of second dielectric material layer 232b, first dielectric material layer 220b, and silicide 208a to provide an electrode material layer. The electrode material layer is deposited using CVD, HDP-CVD, ALD, MOCVD, PVD, JVD, or other suitable deposition technique. The electrode material layer is then recess etched to expose second dielectric material layer 232b and a portion of the sidewalls of first dielectric material layer 220b and to provide electrode material 211d.

The fabrication process previously described and illustrated with reference to FIGS. 13 and 14 is then performed to fabricate spacers 218b. A phase change material, such as a chalcogenide compound material or other suitable phase change material is deposited over exposed portions of second dielectric material layer 232b, spacers 218b, and electrode material 211c to provide a phase change material layer. The phase change material layer is deposited using CVD, HDP-CVD, ALD, MOCVD, PVD, JVD, or other suitable deposition technique. The phase change material layer is then planarized to expose second dielectric material layer 232b and to provide phase change material 213c. The phase change material layer is planarized using CMP or another suitable planarization technique.

The fabrication process previously described and illustrated with reference to FIGS. 16-19 (absent the phase change material deposition illustrated with reference to FIG. 18) is then performed to fabricate memory cell 200d previously described and illustrated with reference to FIG. 6. In another embodiment, the phase change material deposition illustrated with reference to FIG. 18 is not skipped such that memory cells similar to memory cell 200d but including an additional phase change material layer are fabricated.

Embodiments of the present invention provide a resistive memory including resistivity changing memory elements accessed by vertical diodes. The diodes are formed using an epitaxy-free fabrication process. In this way, a 4F² memory cell can be fabricated without an expensive and complex epitaxy process.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. An integrated circuit comprising:
a diode including a first polarity region and a second polarity region, the second polarity region contacting a bottom and sidewalls of the first polarity region;
a first electrode coupled to the diode;
a second electrode; and
resistivity changing material between the first electrode and the second electrode.

2. The integrated circuit of claim 1, further comprising:
spacers defining a cross-sectional width of at least one of the first electrode and the resistivity changing material.

3. The integrated circuit of claim 1, wherein the first electrode comprises a U-shaped electrode.

4. The integrated circuit of claim 1, wherein the first electrode has a first cross-sectional width, and wherein the resistivity changing material has a second cross-sectional width less than the first cross-sectional width.

5. The integrated circuit of claim 1, wherein the resistivity changing material comprises a phase change material.

6. The integrated circuit of claim 1, wherein the first polarity region comprises a P region, and
wherein the second polarity region comprises an N region.

7. A system comprising:
a host; and
a memory device communicatively coupled to the host, the memory device comprising:
a diode including a first polarity region and a second polarity region, the second polarity region contacting a bottom and sidewalls of the first polarity region;
a first electrode coupled to the diode;
a phase change element coupled to the first electrode; and
a second electrode coupled to the phase change element.

8. The system of claim 7, wherein the memory device further comprises:
a word line contacting the second polarity region; and
a bit line coupled to the second electrode.

9. The system of claim 7, wherein the memory device further comprises:
a write circuit configured for programming a state of the phase change element.

10. The system of claim 7, wherein the memory device further comprises:
a sense circuit configured for reading a state of the phase change element.

11. The system of claim 7, wherein the memory device further comprises:
a controller configured to control read and write operations of the phase change element.

12. The system of claim 7, wherein the first polarity region comprises a P region, and
wherein the second polarity region comprises an N region.

13. A memory comprising:
an epitaxy-free vertical diode including a first region having a first polarity implant and a second region having a second polarity implant;
a first electrode coupled to the diode; and
a resistive memory element coupled to the first electrode.

14. The memory of claim 13, further comprising:
a silicide contact coupling the diode to the first electrode.

15. The memory of claim 13, further comprising:
a second electrode coupled to the resistive memory element.

16. The memory of claim 13, wherein the first electrode comprises a U-shaped electrode.

17. The memory of claim 13, further comprising:
spacers defining a cross-sectional width of at least one of the first electrode and the resistive memory element.

18. The memory of claim 13, wherein the resistive memory element comprises a phase change element.

19. The memory of claim 13, wherein the first polarity implant comprises an N implant, and
wherein the second polarity implant comprises a P+ implant.

20. A method for fabricating a memory cell, the method comprising:
fabricating a first polarity word line in a second polarity type substrate using ion implantation;
fabricating an epitaxy-free vertical diode in the substrate using ion implantation, the diode coupled to the word line;
fabricating a first electrode coupled to the diode;
fabricating a resistive memory element coupled to the first electrode; and
fabricating a second electrode coupled to the resistive memory element.

21. The method of claim 20, wherein fabricating the word line comprises:
implanting a first polarity implant into the substrate to provide a first polarity region; and
etching portions of the first polarity region to expose portions of the substrate to provide the first polarity word line.

22. The method of claim 20, wherein fabricating the epitaxy-free vertical diode comprises:
implanting a third polarity implant into the substrate to provide a third polarity region;
implanting a fourth polarity implant into the third polarity region to provide a fourth polarity region; and
etching portions of the third polarity region and the fourth polarity region to expose portions of the substrate to provide the vertical diode.

23. The method of claim 22, wherein fabricating the first polarity word line in the second polarity type substrate comprises fabricating an N+ word line in a P type substrate,
wherein implanting the third polarity implant into the substrate to provide the third polarity region comprises implanting an N implant into the substrate to provide an N region, and
wherein implanting the fourth polarity implant into the third polarity region to provide the fourth polarity region comprises implanting a P+ implant into the N region to provide a P+ region.

24. The method of claim 20, wherein fabricating the first electrode comprises fabricating a U-shaped electrode.

25. The method of claim 20, wherein fabricating the first electrode comprises fabricating a first electrode having a first cross-sectional area, and wherein fabricating the phase change element comprises fabricating a phase change element having a second cross-sectional area greater than the first cross-sectional area.

26. The method of claim 20, wherein fabricating the resistive memory element comprises fabricating a phase change element.

27. A method for fabricating a memory cell, the method comprising:
providing a first polarity type substrate;
depositing a protection material layer over the substrate;
implanting the substrate with a second polarity implant to provide a second polarity region;
implanting the substrate with a third polarity implant to provide a third polarity region above the second polarity region;
depositing a first dielectric material layer over the protection material layer;
etching a portion of the first dielectric material layer to provide an opening exposing a portion of the protection material layer;
implanting the third polarity region below the exposed portion of the protection material layer with a fourth polarity implant to provide a fourth polarity region;
etching the exposed portion of the protection material layer to expose the fourth polarity region;
forming silicide over the exposed fourth polarity region;
forming spacers on sidewalls of the opening;
depositing a first electrode material layer over the silicide between the spacers;
isolating a portion of the first electrode material layer, a portion of the silicide, a portion of the fourth polarity region, a portion of the third polarity region, and a portion of the second polarity region to provide a first electrode, a silicide contact contacting the first electrode, a diode contacting the silicide contact, and a second polarity word line contacting the diode;
depositing a phase change material layer over the first electrode; and
depositing a second electrode material layer over the phase change material layer.

28. The method of claim 27, further comprising:
etching the second electrode material layer and the phase change material layer to provide a phase change element contacting the first electrode and a second electrode contacting the phase change element.

29. The method of claim 27, further comprising:
depositing a second dielectric material layer over the first dielectric material layer; and
etching a portion of the second dielectric material layer to provide the opening exposing the portion of the protection material layer.

30. The method of claim 27, wherein providing the first polarity type substrate comprises providing a P type substrate,
wherein implanting the substrate with the second polarity implant to provide the second polarity region comprises implanting the substrate with an N+ implant to provide an N+ region,
wherein implanting the substrate with the third polarity implant to provide the third polarity region comprises implanting the substrate with an N implant to provide an N region, and
wherein implanting the third polarity region below the exposed portion of the protection material layer with the fourth polarity implant to provide the fourth polarity region comprises implanting the N region below the exposed portion of the protection material layer with a P+ implant to provide a P+ region.
